(19) United States
(12) Patent Application Publication
(10) Pub. No.: US 2002/0008525 A1
(43) Pub. Date: Jan. 24, 2002

(54) TTR phase change detection and hyperframe alignment for DSL

(76) Inventors: Ernest Seagraves, Fremont, CA (US); Yaron Bar-Ness, San Jose, CA (US); Chin Hung, San Jose, CA (US)

Correspondence Address: FENWICK & WEST LLP, TWO PALO ALTO SQUARE, PALO ALTO, CA, 94306, US

(21) Appl. No.: 09/795,052

(22) Filed: Feb. 26, 2001

Related U.S. Application Data
(60) Provisional application No. 60/185,829, filed on Feb. 29, 2000.

(51) Int. Cl. G01R 31/00

(52) U.S. Cl. 324/500

(57) ABSTRACT

A detector provides outputs that are compared to threshold values to determine a valid phase change. Additional discrimination logic may be added to speed the detection process and reduce false detections. Identified patterns relating to NEXT/FEXT frame boundaries allow for NEXT/FEXT frame alignment. Identified patterns for NEXT/FEXT frames in a hyperframe allow for hyperframe alignment.

### RELATED APPLICATIONS

The present application is related to and claims priority from U.S. Provisional Application No. 60/185,829, entitled “TTR Phase Change Detection and Hyperframe Alignment for DSL Modems operating under TCM-ISDN Interference,” filed Feb. 29, 2000, which is hereby incorporated by reference in its entirety.

### BACKGROUND OF THE INVENTION

1. Field of the Invention

The present invention relates generally to DSL service for Internet access and, more specifically, to DSL service using a TCM ISDN standard and improved transmission methods disclosed herein.

2. Technical Background

The Internet has enjoyed tremendous growth and technical innovation. Given its popularity, improved Internet access and speed is in great demand. Digital Subscriber Line (DSL) is a high speed data service that provides vastly improved speeds than conventional dial up connections. DSL has been deployed in various forms throughout the world. In particular, the Asia DSL market is quite advanced with expansive deployments in Japan, Korea, and China. Asia has three standards or specifications that are widely used with DSL: Annex A (both G.dmt and G.lite), Annex C (including G.dmt and G.lite), and Annex H.

Annex A is a very common type of DSL deployed throughout the world today. G.dmt Annex A has replaced ANSI T1.413 Issue 2, an early version of discrete multi-tone (DMT) line coding, as the most widely used form of asymmetric DSL (ADSL). Since that time, G.dmt has been adopted as one of two worldwide standards for ADSL, given 24 gauge copper wires with loops not exceeding 18,000 feet. With G.dmt line coding, DSL devices adjust the bits per second on a per channel basis to adapt to signal interferences (for example, from bridge taps) and noise (for example, from AM radio). G.dmt carries data in discrete frequency “bins” of about 4 kHz in width, each of which is independently rate adaptable depending on the noise and signal attenuation for each bin.

The other Annex A ADSL is G.lite. This standard was developed to provide the industry with an alternative to G.dmt that would work efficiently on longer loops, and is easy to install. In general, the goal was to develop a line coding technology that would actually spur the growth of the market to reach mass potential. Given the typical 24 gauge copper wire, G.lite performs very well up to 21,000 feet and does not require filters or splitters to alleviate any interference between the POTS line and the DSL.

Annex C ADSL is responsive to special network characteristics found in Japan. Japan employs a unique Integrated Services Digital Network (ISDN) that is referred to as the Time Compression Multiplexed (TCM) ISDN. TCM ISDN is a time division transmission with a high transmit signal level and poor low pass filtering that causes a significant level of cross talk interference. Furthermore, poorly insulated cables (e.g., pulp-based insulation) are used in Japan, which causes increased attenuation at high frequencies.

Within Annex C, there are two types of transmission modes: far end cross talk bit map (FBM) mode and dual bit map (DBM) mode. FBM mode is the more simple of the two. FBM mode transmits only during a far end cross talk (FEXT) cycle to match transmission direction of ISDN. The limitation of FBM mode is that the bit rate is limited because it uses only about 37% of the symbols. This translates to data rates of only a little more than 3 Mbps downstream for full rate, and about 1 Mbps for G.lite ADSL. The second type of transmission, DBM mode, is more difficult to implement since some transmission is on the FEXT cycle. The difficulty is worthwhile to overcome, however, because in transmission lines having a sufficient signal to noise ratio (SNR), rates up to Annex A levels can be achieved.

Annex H is similar to Annex C FBM, except that it is symmetric and transmits only during FEXT time, while using all available frequency bins. Annex H requires a DSP core powerful enough to handle up to 255 bins upstream and downstream. The benefit of Annex H is that it provides a symmetric DSL for Japan markets and can achieve rates higher than Annex C G.dmt FBM because more downstream bins are used.

Japan's unique TCM ISDN ping pong modulation can cause particularly strong cross talk interference within DSL systems. Crosstalk is present in data transmission when two wires are close enough to each other that one of them generates energy in the other due to coupling. The two potential types of crosstalk coupling are near-end crosstalk (NEXT) and FEXT. Generally, the effects of FEXT are minimal and most errors are due to NEXT. Unfortunately, trellis-coded schemes and other well known error detection and correction schemes do not handle bursty errors in the transmission. The previously discussed DBM technique synchronizes DSL transmission with the TCM ISDN transmission in adjacent pairs to minimize the effect of crosstalk. More specifically, TCM ISDN transmits in one direction at a time and switches direction according to a timing reference at 400 Hz to which the entire system is synchronized. The timing reference is referred to as a TCM Timing Reference (TTR).

The TTR is the master clock signal for determining when the modems should transmit. In general, the CO modems transmit during one half of the TTR period, while the CPE modems transmit during the other half of the TTR period. All ISDN and G.lite timing is based on the TTR signal. Within the same wire bundle, the transmissions create an alternating noise environment. During the first half period of the TTR a local modem is dominated by ISDN NEXT noise, and during the next half period ISDN FEXT noise dominates. The reverse is true for a remote modem in communication with the local modem. The local modem may be referred to as an ADSL Termination Unit-Central (ATU-C) modem or Central Office (CO) modem. The remote modem may be referred to as an ADSL Termination Unit-Remote (ATU-R) modem or Customer Premises Equipment (CPE) modem.

For optimal G.lite performance, modems are synchronized with the time varying noise environment. G.lite includes multiple tones, each of which is modulated with different data. Tone 64 may be used as the TTR signal for synchronization. The TTR is transmitted by the CO (master) and synchronized to by the CPE (slave). A second pilot tone is added to aid in the synchronization. Synchronization is accomplished by detecting and tracking the second pilot tone which may be a phase shift key modulated signal. The second pilot tone changes its phase near the rising and falling edges of the TTR signal. Tone 48 may be used as the second pilot tone, and may be a carrier at 207 kHz with phase changes of 90 degrees occurring at the boundaries between the NEXT and FEXT symbols.

At issue is the detection of the phase changes in tone 48, the second pilot signal. Since the G.lite frame rate is not a multiple of 400 Hz, the boundaries between the NEXT and FEXT channels for the modem are not obvious. Detection of the second pilot tone identifies the boundaries between the NEXT and FEXT channels. Once obtained, frame synchronization is also obtained since the phase changes occur at frame boundaries. The second pilot signal is generated at the CO or ATU-C side so detection is not an issue for the CO. However, at the CPE or ATU-R side there is no reference signal. Thus, the reference signal must be derived from the CO's transmit signal. To accomplish this, Annex C specifies that bin 48 be used during training to transmit a tone which is phase modulated at 400 Hz synchronized with the TTR signal.

The G.lite has a period of 345 frames that are collectively referred to as a hyperframe. Although the phase of the sliding window is asynchronous with the TTR signal, the pattern is fixed to the 345 frames of the hyperframe. This results in misalignment of the hyperframe.

Improved detection methods of the second pilot tone by the CPE modem would allow for superior determination of frame boundaries between NEXT and FEXT channels. Such improved detection methods would further allow for frame synchronization. In addition to improved detection methods, it would further be an advancement in the art to provide improved methods for aligning a hyperframe based on frame alignments.

### BRIEF SUMMARY OF THE INVENTION

The present invention provides an innovative method and design for improved phase change detection in the presence of heavy TCM ISDN interference. One embodiment of the present invention includes a detector for receiving a phase changing tone and generating outputs relating to the phase changes. The detector includes a matched filter. The filter has certain properties including that it is orthogonal with other signals in the band, orthogonal with the tone in the absence of phase change at the detection frequency, and correlates with the phase changing tone at the detection frequency. The detector receives the phase changes and generates corresponding metrics. The detector compares the metrics to threshold values to determine if they indicate a valid phase change. Additional discrimination logic may be added to speed the detection process and reduce false detections.

This embodiment of the present invention further includes a state machine that couples to the detector and reviews the metrics and compares the metrics to known patterns. Certain metrics are indicative of peaks that relate to NEXT/FEXT frame boundaries. The state machine further aligns the NEXT/FEXT frames based on the boundary locations.

The present invention further provides hyperframe alignment based on known patterns of FEXT and NEXT frames. In one embodiment, a first series of five contiguous FEXT frames is located within the hyperframe. A second series of five contiguous FEXT frames is then located. The distance between the first and second series is found to determine hyperframe alignment based on the known pattern.

These and other embodiments are described in the detailed description of the invention section. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the inventive subject matter.

### BRIEF DESCRIPTION OF THE DRAWINGS

FIG. 1 is a timing diagram illustrating the timing relationship between the TTR signal, ISDN, and G.lite components;

FIG. 2 is a block diagram illustrating the concept of FEXT and NEXT channels;

FIG. 3 is a timing diagram illustrating the timing relationship between the TTR signal, ISDN NEXT/FEXT intereference, and the G.lite transmit frames;

FIG. 4 is a timing diagram illustrating the timing relationship between a hyperframe and the TTR signal;

FIG. 5 is a flow diagram of a method for determinig frame alignment in accordance with one embodiment of the present invention;

FIG. 6 is a flow diagram of a sub-process for determining frame alignment in accordance with one embodiment of the present invention;

FIG. 7 is a flow diagram of a sub-process for determining frame alignment in accordance with one embodiment of the present invention;

FIG. 8 is a flow diagram of a sub-process for determining frame alignment in accordance with one embodiment of the present invention;

FIG. 9 is a flow diagram of a method for performing hyperframe alignment in accordance with one embodiment of the present invention;

FIG. 10 illustrates time domain representations of the impulse response of a detector filter in accordance with one embodiment of the present invention;

FIG. 11 is a block diagram illustrating the structure of a metric calculation in accordance with one embodiment of the present invention;

FIG. 12 is a graphical representation of a frequency response of a detector in accordance with one embodiment of the present invention;

FIG. 13 is another graphical representation of a frequency response of a detector in accordance with one embodiment of the present invention;

FIG. 14 is another graphical representation of a frequency response of a detector in accordance with one embodiment of the present invention;

FIG. 15 is another graphical representation of a frequency response of a detector in accordance with one embodiment of the present invention;

FIG. 16 is another graphical representation of a frequency response of a detector in accordance with one embodiment of the present invention;

FIG. 17 is another graphical representation of a frequency response of a detector in accordance with one embodiment of the present invention;

FIG. 18 is another graphical representation of a frequency response of a detector in accordance with one embodiment of the present invention;

FIG. 19 is another graphical representation of a frequency response of a detector in accordance with one embodiment of the present invention; and

FIG. 20 is a flow diagram of a method for detecting phase change of a signal in accordance with one embodiment of the present invention.

### DETAILED DESCRIPTION OF THE INVENTION

In the following description, numerous specific details are provided to provide a thorough understanding of embodiments of the present invention. One skilled in the relevant art will recognize, however, that the present invention can be practiced without one or more of the specific details, or with other methods, components, protocols, etc. In other instances, well-known operations are not shown or described in detail to avoid obscuring aspects of the present invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

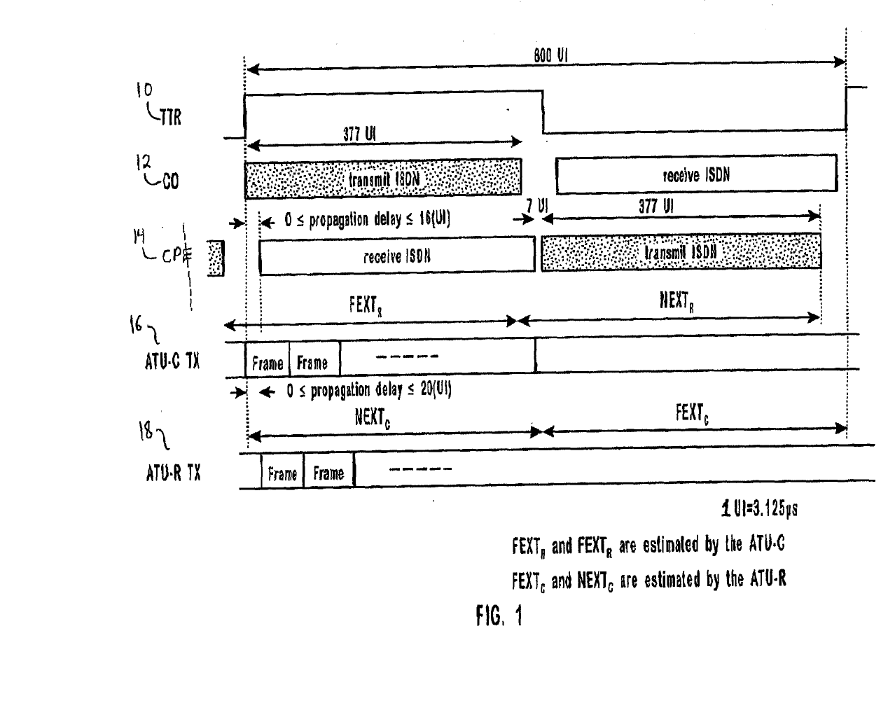

One embodiment of the present invention provides an improved method for detecting a phase change in the second pilot tone that is specific to G.lite Annex C. Referring to FIG. 1, a timing period is shown for a TCM ISDN system. More specifically, FIG. 1 illustrates the relationship between the TTR signal 10 at 400 Hz and the ISDN transmit and receive channels of the CO 12 and a CPE 14. The TCM ISDN system transmits in one direction at a time and then switches direction based on the TTR signal 10. Thus, during a first half period the CO 12 transmits and the CPE 14 receives, and then directions are reversed during the second half period.

FIG. 1 further illustrates noise interference from NEXT and FEXT. During the first half period, The ATU-C 16 is dominated by NEXT noise during the first half period and dominated by FEXT noise during the second half. The ATU-R 18 experiences the reverse. As NEXT noise is signifcantly greater than FEXT noise, it is preferable to transmit during FEXT noise. Note, however, that given a sufficient SNR, transmissions can also occur during NEXT noise (e.g., DBM mode).

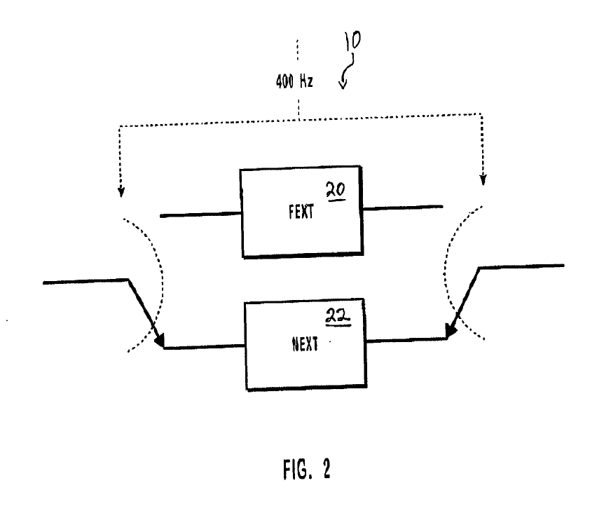

FIG. 2 illustrates the channel model concept for CO and CPE. Switching between FEXT and NEXT channels 20, 22 is determined by the 400 Hz TTR signal 10. The two different conceptual channels are really the same channel operating under two different types of crosstalk noise. The FEXT channel 20 exists during FEXT time, while the NEXT channel 22 exists during NEXT time. Each of these conceptual channels is associated with a particular SNR curve, and is capable of a different bit carrying capacity.

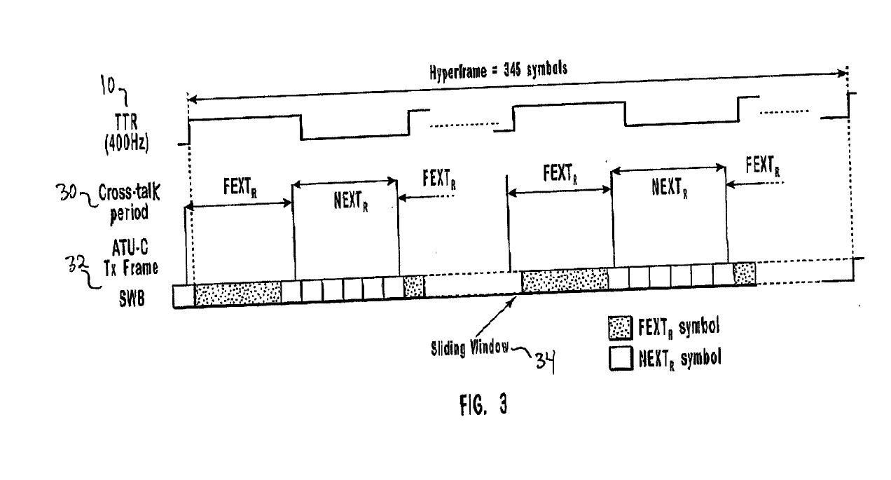

Referring to FIG. 3 a timing diagram illustrating the relationship between the TTR signal 10, the FEXT/NEXT interference periods 30, and the ATU-C transmit frames 32 are shown. A “Sliding Window” operation 34 is indicated and defines the procedures to transmit symbols under the cross-talk noise environment synchronized to the period of the TTR. The FEXT_{R} symbol represents the symbol completely inside the FEXT_{R} duration. The NEXT_{R} symbol represents the symbol containing any NEXT_{R} duration. Thus, there are more NEXT_{R} symbols than FEXT_{R} symbols.

The ATU-C associated with the ATU-C transmit frames 32 determines which transmission symbol is a FEXT_{R} or NEXT_{R} symbol according to the Sliding Window 34 and transmits it with a corresponding bit table. Similarly, the ATU-R (not shown) decides which transmission symbol is a FEXT_{C} or NEXT_{C} and transmits it with a corresponding bit table. Although the phase of the Sliding Window 34 is asynchronous with the TTR signal 10, the pattern is fixed to the 345 frames of the hyperframe.

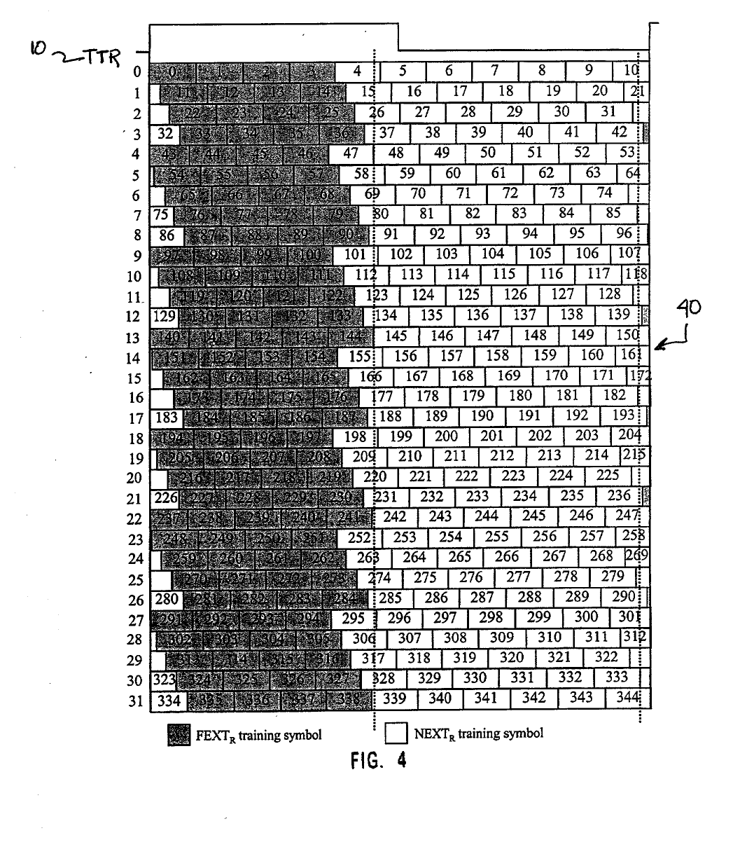

Referring to FIG. 4, a timing diagram illustrating the relationship between the TTR signal 10 and a hyperframe 40 is shown. The hyperframe 40 corresponds to the ATU-C and includes 345 frames that are referred to as G.lite frames. The G.lite frames are mapped to the NEXT/FEXT channels. As illustrated by FIG. 4, the TTR signal 10 and the G.lite ATU-C frames are not aligned. Over a period of 345 G.lite frames the TTR signal 10 spans 32 or 34 periods depending on the cyclic prefix mode. This least common multiple period is used to define the hyperframe.

The primary difference between the NEXT and FEXT channels is the additive interference. Any frame (sometimes referred to as symbols) that is partially affected by the NEXT interference is treated as though it passed through the NEXT channel. The shaded frames represent data treated as transmitted through the FEXT channel. The remaining frames are treated as though they were transmitted through the NEXT channel.

The second pilot tone has a phase change of 90 degrees occurring at the boundaries between the NEXT and FEXT symbols (e.g., on the transitions between shaded and non-shaded frames in FIG. 4). The detection of the phase change in the second pilot tone, tone 48, allows detection of the boundaries between the NEXT and FEXT channels. Once boundary detection is achieved, frame synchronization is achieved because the phase changes occur at frame boundaries.

One approach used in synchronization to a known repeating event is to employ an event indicator and a state machine. The event indicator is a detector whose output may be a binary random variable indicating if the event is present or not with some probability of error. The output is delivered into a state machine that looks for patterns in the event indicator's output and correlates with known patterns in the repetition rate of the underlying event. In one embodiment, a Markov model may be used to determine the overall behavior of the scheme.

Here, the phase change in the second pilot tone that occurs at the boundaries between the NEXT and FEXT symbols can be used as the known repeating event. Two patterns may be used to achieve hyperframe alignment. First, the phase change of the second pilot tone occurs at frame boundaries. This allows for frame alignment, as well as TTR alignment.

The second pattern is the “Sliding Window” function defined above. Referring once again to FIG. 4, the hyperframe 40 has an established pattern that repeats every hyperframe 40 (e.g., every 345 frames). One feature of the pattern is that the number of contiguous FEXT frames is 4 except for two occasions where it is 5. The runs of 5 FEXT contiguous frames occur in frames 140-144 and 237-241. Also the number of contiguous NEXT frames is always greater than 5. Furthermore, the distance between the two runs is 97 frames or 247 frames, depending on which group of 5 FEXT frames the distance count begins (e.g., from frame 140 to frame 237 is 97 frames, while from frame 237 to frame 140 is 247 frames). The hyperframes can be synchronized based on these identified patterns and pattern features.

A system in accordance with one embodiment of the present invention first attains frame alignment and then obtains hyperframe alignment. In this embodiment, the frame alignment and hyperframe alignment functions are broken down into two separate functions that share the use of an indicator function. Each function can be carried out, for example, by a set of codes or software instructions running on a digital signal processor (DSP).

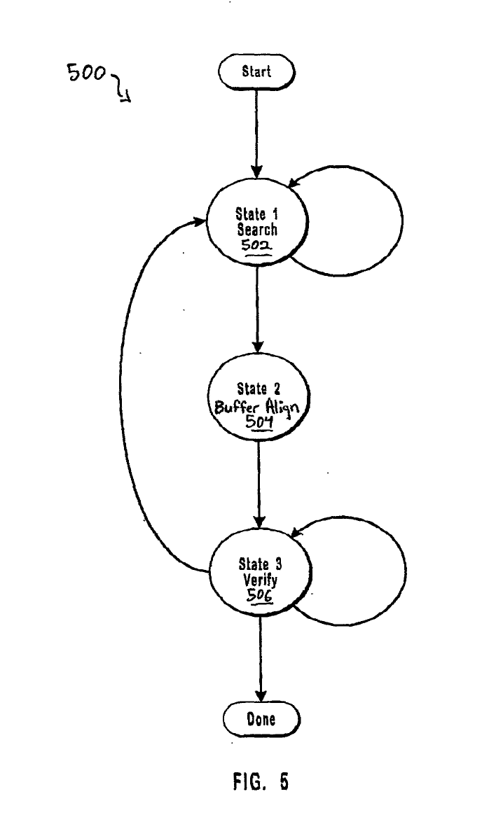

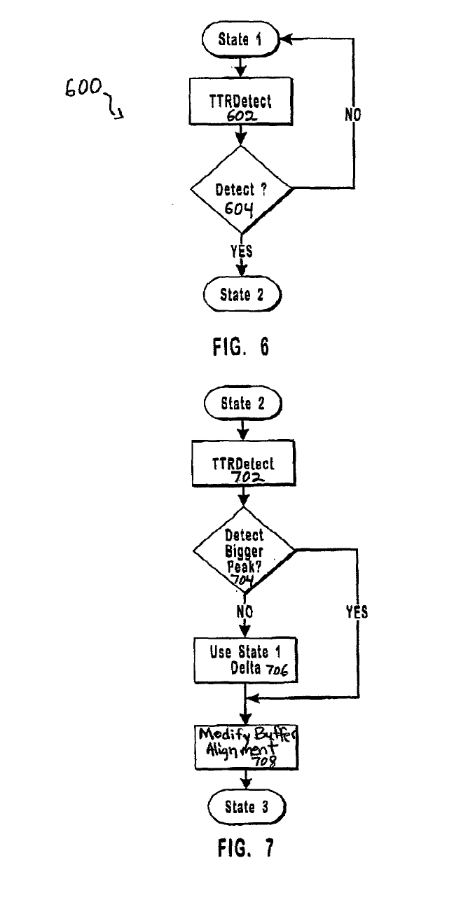

Referring to FIG. 5, a flow diagram 500 illustrating a method for frame alignment in accordance with one embodiment of the present invention is shown. The frame alignment is accomplished by using the fact that the phase changes (e.g., of tone 48) occur on frame boundaries. The state machine illustrated has 3 states. On initialization the state machine is set to State 1. State 1 502 searches for the initial indication/detection. One embodiment of this search process is shown in the flow diagram 600 of FIG. 6. The process performs a TTRDETECT 602 for an initial indication/detection. The process then queries 604 as to whether there is a detection. If not, the process returns to the beginning of State 1. Following an initial indication/detection, however, the state machine transitions into State 2.

In State 2 504 the indicator function (e.g., TTRDETECT) is used to search for an indication/detection metric larger than the previous. This helps eliminate boundary condition problems. This process is shown in the flow diagram 700 of FIG. 7. The process performs a TTRDETECT 702 for indication/detection. The process then queries 704 to determine if a larger peak is found. If so, then the new offset is used to modify 708 the buffer alignment established by state 2 of FIG. 5. Otherwise the offset found in the initial detection is used 706 to modify 708 the buffer alignment established by state 2 of FIG. 5 for the associated frame. This is to align the detection peak to the frame boundary. State 2 lasts only one frame and then transitions to State 3. Because the output of the indicator function at a phase change is a triangular pulse, a peak early in a frame will also appear as a peak late in the previous frame. This requires some discrimination. The purpose of State 2 is to check for the boundary condition, and to align the sample buffers to the DSL frames using the appropriate offset. This will force the detector/indicator peaks to fall on buffer boundaries since phase changes occur on frame boundaries.

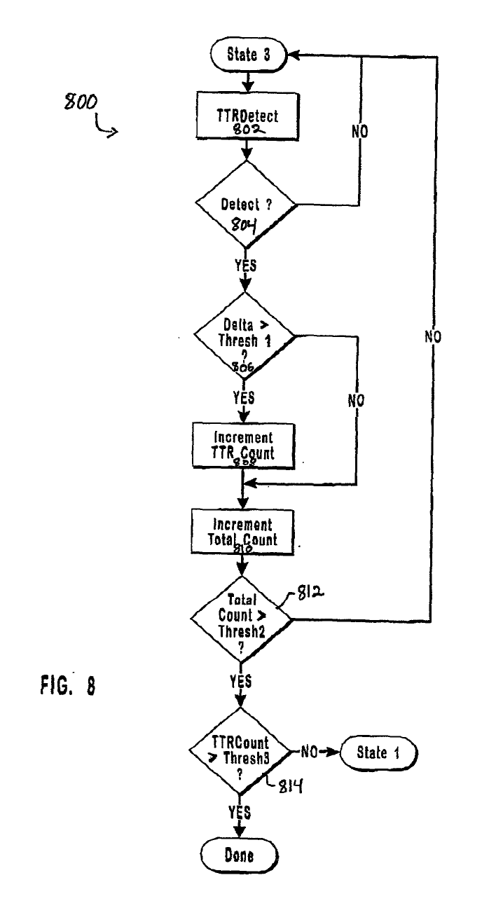

State 3 506 is for verification of the new alignment. This process is shown in the flow diagram 800 of FIG. 8. In state 3, every frame is passed through the TTRDETECT 802. The process then queries 804 for a detection. If a valid indication is found then the location of the peak is checked to verify that the peak is close to the frame boundary 806 (e.g., if the detected peak is within 8 samples of the edge of the frame). If it is close to the frame boundary then a “good” detection is declared and counter M (e.g., xTTRCount), indicating a TTR count, is incremented 808. A total iteration counter N (e.g., kTTRTotalCount), indicating a total count, is incremented 810 every iteration. The process queries 812 to determine if a threshold (e.g., kTTRTotalCountThresh or Thresh2=5) is reached for the total count N. The search is repeated until the total count threshold is reached. The TTR count M is compared 814 to a threshold (e.g., kTTRCountThresh or Thresh3=4) and success or failure is declared. If successful, then the frame alignment is completed and the process may proceed to hyperframe alignment. If not successful, the frame alignment proceeds to State 1 502 and begins anew.

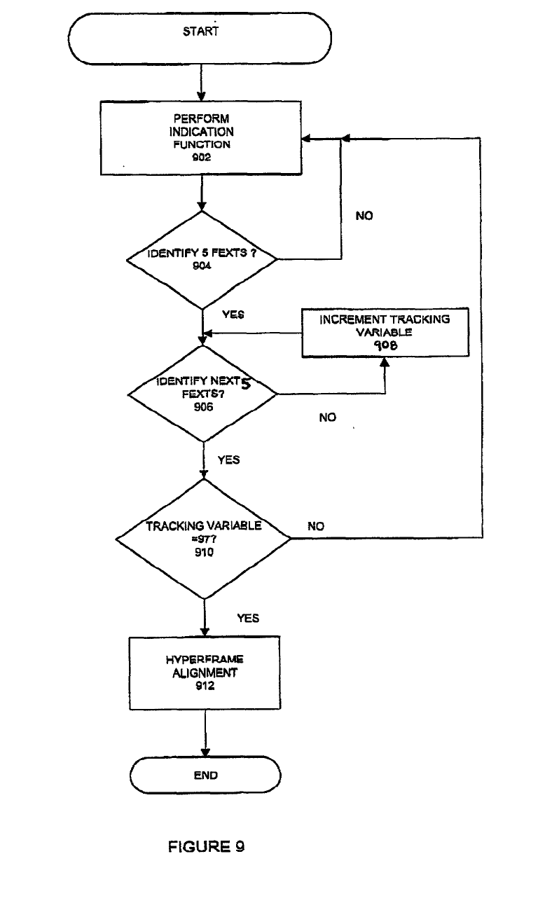

Referring to FIG. 9 a flow diagram 900 representing the process for hyperframe alignment in accordance with one embodiment of the present invention is shown. At this point, the NEXT and FEXT frame boundaries have been identified. This process makes use of the same indication function 902 (e.g., TTRDETECT) to search for the runs of 5 contiguous FEXT frames described above. This pattern of 5 frames between phase changes is unique in that it occurs in only 2 places within the hyperframe. The indicator function 902 performs more tasks than providing a binary indication. It also provides the offset of the indication from the start of the frame, the metric associated with the peak, as well as the number of previous frames that had no detections (e.g., xTTRPreviousNoDetects).

The process 900 queries 904 as to whether the 5 FEXT frames have been located. The process 900 further queries 906 as to the location of the next 5 FEXT frames. A tracking variable is incremented 908 to monitor the distance between the runs of 5 FEXT frames. The tracking variable is monitored 910 and when the tracking variable is equal to 97, it is likely frame 241 has been detected and that hyperframe alignment exists 912. For a false detection to occur, there must be a false detection of a run of exactly 5 FEXT frames, a non-detection of runs of 5 for the next 96 frames, and then a second detection of a run of 5 on the next frame. This unlikely combination of events is quite restrictive and deemed to rarely occur.

Embodiments of a detector in accordance with the present invention will now be discussed. The basic operation of the detector/indicator function is to calculate a decision metric at each instant of time and compare this to a threshold. In one embodiment, the detector includes the following properties. First, the detector correlates with the phase changing of the second pilot tone. As discussed above, the second pilot tone may be selected as tone 48. Second, the detector is orthogonal to the second pilot tone (e.g., tone 48) with no phase changes. Third, the detector is orthogonal to the first pilot tone (e.g., tone 64). Finally, the detector should also have good noise immunity properties.

In one embodiment, the detector includes a matched filter designed with the above four described properties. The metric is the instantaneous output energy of the matched filter. The filter may be embodied as a cisoid centered in bin 48 and modulated using the sgn0 function.

Rather than derive the optimal detector, a solution is stated and its properties are established. A detector filter may be given by:

x(k):=e^{-j·ω·k}·sgn(k)

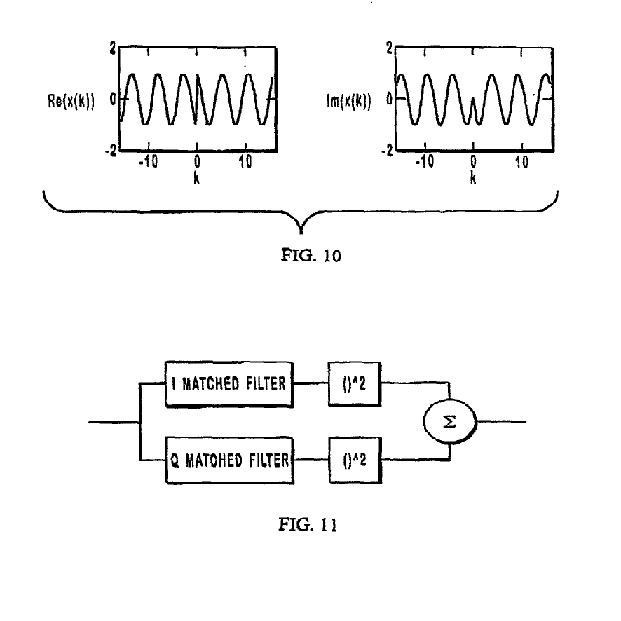

Referring to the graphical representations of FIG. 10, time domain representations of the detector filter impulse response are shown. In one embodiment, the filter incorporates a window function to increase the filter's immunity to noise.

The four properties outlined above will now be discussed and verified with respect to a detector in accordance with the present invention. With respect to the first property, correlating to the second pilot tone, at the phase change the second pilot tone 48 can be defined as:

$$y ( k ) := sin ( ω48 k + \frac{π}{2} \cdot Φ ( k ) )$$

where Φ(k) is a unit step function

The output of the detector at the phase change can be written as:

$${\int }_{- L}^{L} {ⅇ}^{- 1 j \cdot ω48 \cdot t} \cdot sgn ( t ) \cdot sin ( ω48 \cdot t + \frac{π}{2} \cdot Φ ( t ) ) ⅆ t := {\int }_{- L}^{0} - {ⅇ}^{- 1 j \cdot ω48 \cdot t} \cdot sin ( ω48 \cdot t ) ⅆ t + {\int }_{0}^{L} {ⅇ}^{- 1 j \cdot ω48 \cdot t} \cdot cos ( ω48 \cdot t ) ⅆ t$$

The periodicity allows the first term integration limits to be shifted by L.

$${\int }_{- L}^{L} {ⅇ}^{- 1 j \cdot ω48 \cdot t} \cdot sgn ( t ) sin ( ω48 \cdot t + \frac{π}{2} \cdot Φ ( t ) ) ⅆ t := {\int }_{0}^{L} {ⅇ}^{1 j \cdot π} \cdot {ⅇ}^{- 1 j \cdot ω48 \cdot t} \cdot sin ( ω48 \cdot t ) ⅆ t + {\int }_{0}^{L} {ⅇ}^{1 j \cdot \frac{π}{2}} \cdot {ⅇ}^{- 1 j \cdot ω48 \cdot t} \cdot sin ( ω48 \cdot t ) ⅆ t$$

$${\int }_{- L}^{L} {ⅇ}^{- 1 j \cdot ω48 t} \cdot sgn ( t ) \cdot sin ( ω48 \cdot t + \frac{π}{2} \cdot φ ( t ) ) ⅆ t := \sqrt{2} \cdot {ⅇ}^{1 j \cdot 3 \cdot \frac{π}{4}} \cdot {\int }_{0}^{L} {ⅇ}^{- 1 j \cdot ω48 \cdot t} \cdot sin ( ω48 \cdot t ) ⅆ t$$

Using:

$${\int }_{0}^{L} {ⅇ}^{- 1 j \cdot ω48 t} \cdot sin ( ω48 \cdot t ) ⅆ t := \frac{- L \cdot j}{2}$$

This simplifies to:

$${\int }_{- L}^{L} {ⅇ}^{- 1 j \cdot ω48 \cdot t} \cdot sgn ( t ) \cdot sin ( ω48 \cdot t + \frac{π}{2} \cdot Φ ( t ) ) ⅆ t := \frac{L \cdot ( 1 + j )}{2}$$

Since the detector is orthogonal to the other signals the detection distance is given by:

$$\vert {\int }_{- L}^{L} {ⅇ}^{- 1 j \cdot ω48 \cdot t} \cdot sgn ( t ) \cdot sin ( ω48 \cdot t + \frac{π}{2} \cdot φ ( t ) ) ⅆ t \vert := \frac{L}{\sqrt{2}}$$

The above result shows that the performance of the detector improves as the length of the filter increases. This is the square root of the detectors output energy. Thus, the filter is correlated with the phase changing of the second pilot tone by an amount proportional to the length of the detector. Therefore, out detectability is not limited.

A perfect matched filter would provide an output of:

$${\int }_{- L}^{L} sin ( ω 48 \cdot t + \frac{π}{2} \cdot φ ( t ) ) \cdot sin ( ω48 \cdot t + \frac{π}{2} \cdot φ ( t ) ) ⅆ t := L$$

Although a perfect matched filter, such a filter is not orthogonal to the non-phase changing tone 48. The filter matched exactly to the phase changing signal has a cross-correlation with the non-phase changing tone of:

$${\int }_{- L}^{L} sin ( ω 48 \cdot t + \frac{π}{2} \cdot φ ( t ) ) \cdot sin ( ω48 \cdot t ) ⅆ t := \frac{L}{2}$$

Thus, the distance between detection and no detection is L/2. The detector of the present invention outperforms this result by 3 dB.

The properties of the detector being orthogonal to the second pilot tone with no phase changes and orthogonal to the TTR signal are now discussed. L is chosen such that it is an integer multiple of the period of the second pilot tone and the TTR signal (e.g., tone 48 and tone 64, respectively). One skilled in the art will appreciate that different tones may be used depending on factors such as the modulation scheme being employed. The present invention is not intended to be limited to any one type of modulation scheme or communication system. For n=48,64 the following equations hold. The first step is to expand the integral:

$${\int }_{- L}^{L} {ⅇ}^{- 1 j \cdot ω 48 \cdot t} sin ( ω n \cdot t ) \cdot sgn ( t ) ⅆ t := {\int }_{- L}^{0} - {ⅇ}^{- 1 j \cdot ω48 \cdot t} \cdot sin ( ω n \cdot t ) ⅆ t + {\int }_{0}^{L} {ⅇ}^{- 1 j \cdot ω48 \cdot t} \cdot sin ( ω n \cdot t ) ⅆ t \qquad 5$$

Since the integral's argument is periodic and completes an integer number of periods in L, the integral's limits can be shifted by a multiple of L.

$${\int }_{- L}^{L} {ⅇ}^{- 1 j \cdot ω 48 \cdot t} sin ( ω n \cdot t ) \cdot sgn ( t ) ⅆ t := {\int }_{- L}^{0} - {ⅇ}^{- 1 j \cdot ω48 \cdot t} \cdot sin ( ω n \cdot t ) ⅆ t + {\int }_{0}^{L} {ⅇ}^{- 1 j \cdot ω48 \cdot t} \cdot sin ( ω n \cdot t ) ⅆ t$$

By recombining the integrals we find:

$${\int }_{- L}^{L} {ⅇ}^{- 1 j \cdot ω47 \cdot t} \cdot sin ( ω n \cdot t ) \cdot sgn ( t ) ⅆ t := {\int }_{0}^{L} 0 ⅆ t$$

This shows that for any n, the detector is orthogonal to sin (ωπI) as long as the L is a multiple of the period. So for tone 48 and 64 to be orthogonal, to this detector the minimum length is 32, i.e. L=16 samples.

A fourth property of the detector is for improved noise immunity properties. Using Parsaval's relation and assuming unit white noise as input to the filter, we can determine the overall noise gain.

$${\int }_{- L}^{L} {( \vert {ⅇ}^{- 1 j \cdot ω48 \cdot t} \vert )}^{2} ⅆ t := 2 \cdot L$$

For unit noise energy density the output noise energy grows linearly with the length of the filter. The detector output grows linearly in output level with L, but the energy grows as the square. The detector output power is (L/2)². Thus, the SNR at the output of the detector is:

$$\frac{k \cdot \frac{{L}^{2}}{4}}{2 L} := k \cdot \frac{L}{8}$$

Here, k is an undetermined constant. So the SNR in dB is 10 log 10(kL/8). For each doubling of the filter length the SNR improves by 3 dB. The actual SNR is highly dependent on the specific characteristics of the noise involved in a given environment.

Referring to FIG. 11, the structure of a metric calculation in accordance with one embodiment of the present invention.

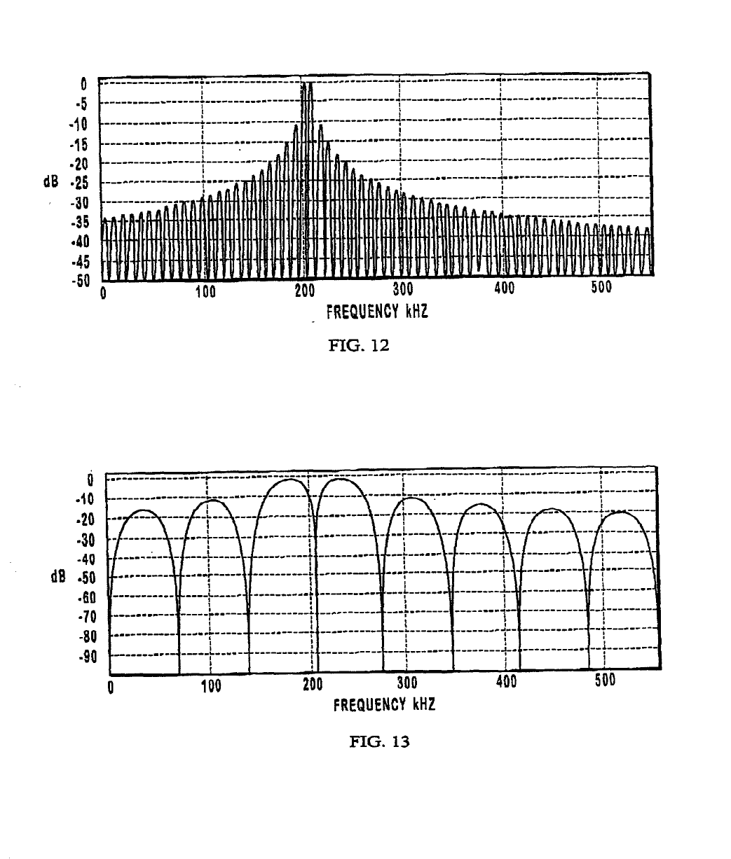

FIGS. 12 and 13 illustrate a frequency response of a detector in accordance with one embodiment of the present invention. More specifically, these figures illustrate the frequency response of a detector for L=128,16.

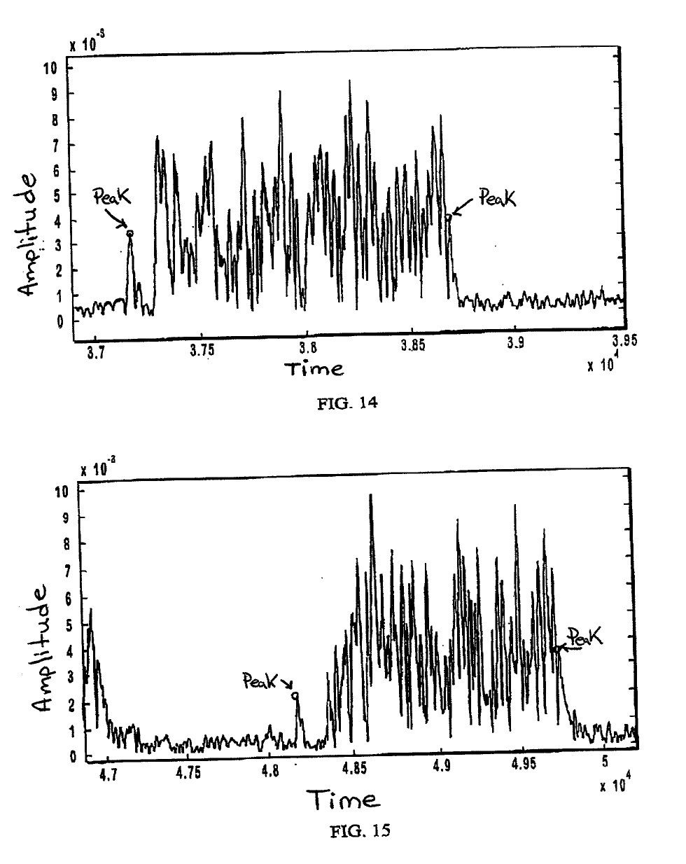

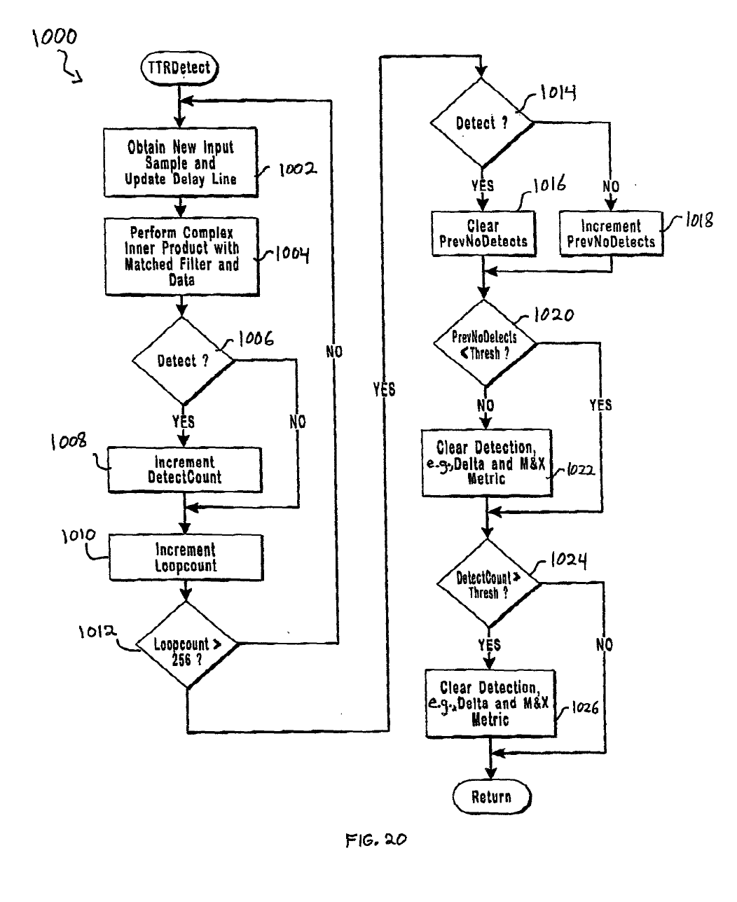

Referring to FIGS. 14 to 19, a detector's output with additive TCM ISDN interference at various levels is shown. Form these graphical representations it can be seen that simply comparing the output (metric) to a threshold is not sufficient as an indication of the phase change of the second pilot tone. The valid peaks are circled.

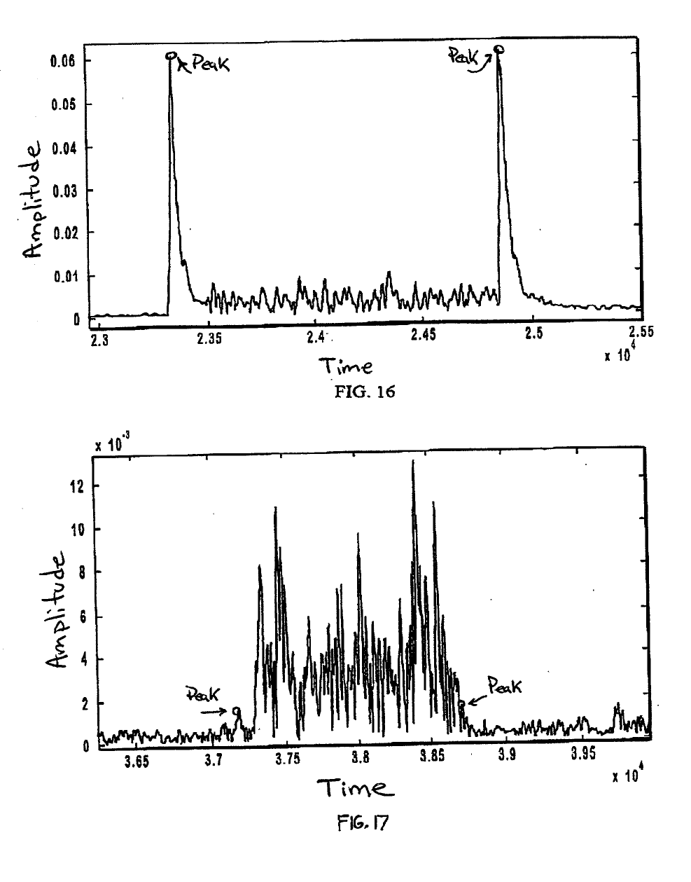

Applying the matched filter (discussed above) to the signal generates the desired metric. The next step in a detection problem is to determine the threshold to compare the metric against. From the above plots, it is clear that the threshold should not be based on total energy. The energy in bin 48 can be used to determine a threshold level. This gives a threshold that is related to the metric of a valid peak. In one embodiment, the threshold is about ½ of value of the metric at a valid peak. In scenarios such as that shown in FIG. 16, this works quite well.

However, if the same logic is applied to the scenario of FIG. 15, the noise is above the threshold much more than the valid peaks. Thus, the chance of finding a valid peak is quite low. Clearly a false detection problem exists when we use the basic indicator/detector function. From the detector output plots and understanding that the phase changes separate the NEXT and FEXT time, schemes and patterns can be identified and exploited to minimize false detection.

Having a metric and a threshold, additional discrimination logic is further incorporated to minimize the probability of false detection while keeping the probability of missed detection at acceptable rates. This implies a Neyman-Pearson approach to the detection problem. Instead of deriving the optimal solution, the invention adds further discrimination logic until performance requirements are met.

In one embodiment, the discrimination logic includes a first discriminator to eliminate any frame that has too many metric points above the threshold. Having several points above the threshold is a characteristic of the detector output in a NEXT noise environment. Such discrimination helps to eliminate the heavy NEXT noise from causing too many false detects.

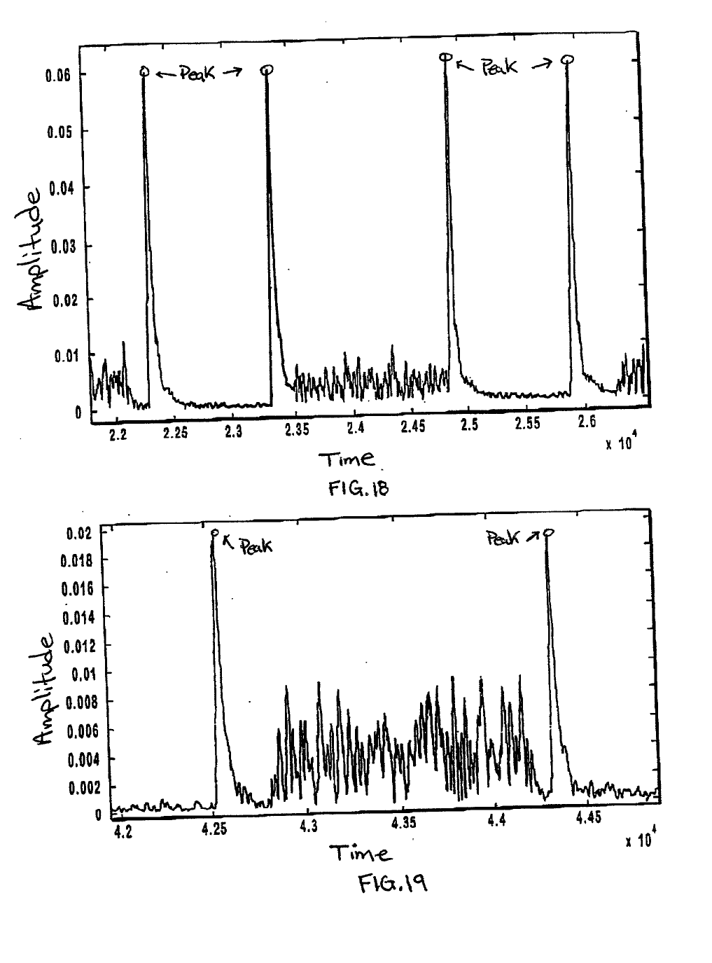

The discrimination logic may further include a second discriminator for scenarios such as in FIG. 18. In this case the NEXT noise is mostly below the threshold but frequently pops above it. This mimics the behavior of a valid peak. To discriminate against this situation, the second discriminator makes use of the realization that the peak at the transition from FEXT to NEXT has a minimum of 4 previous frames with FEXT noise (lower noise). To take advantage of this, the second discriminator looks at the previous 4 frames. If any of the four previous frames had a metric that was above the threshold, then the current frame is invalidated as a possible transition. The two previous techniques discriminate against high and medium NEXT noise scenarios. The low NEXT noise can be handled the same as FEXT noise by using the simple detection process.

FIG. 20 shows a flow diagram 1000 that illustrates the operation of an indication function employing discrimination logic in accordance with one embodiment of the present invention. The process starts by obtaining 1002 a new input sample and updating a delay line. The process then performs 1004 a complex inner product with matched filter and data. A query 1006 is made as to whether there is detection. If so, then a variable (e.g., DetectCount) is incremented 1008 and a loopcount variable is incremented 1010.

A query is then made 1012 to determine if the loopcount variable exceeds a threshold value of 256. If so, then the process continues to another detection query 1014. If there is a detection, the process continues and clears 1016 a variable (e.g., prevnodetects). If no detection, the process increments 1018 the prevnodetects variable. A query 1020 is then made to determine if the prevnodetects variable is less than a threshold value. If not, then the process clears 1022 detection variables. A query 1024 is then made to determine if a detectcount variable is greater than a threshold value. If so, then the process clears 1026 detection variables. In this manner, the indication and discrimination logic may be realized.

Note that the principles of the present invention can be implemented by hardware, software, firmware, or any combination thereof. In one embodiment, for example, the techniques described herein are carried out by a set of codes or software instructions executed by a DSP included in the associated transceiver.

The above description of illustrated embodiments of the invention is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined by the following claims, which are to be construed in accordance with established doctrines of claim interpretation.

What is claimed is:

1. A method for detecting at a remote modem a phase change of a pilot tone to indicate synchronization with a TTR signal, the method comprising:
configuring a detector to correlate with the phase change;
configuring the detector to be orthogonal to the pilot tone in the absence of a phase change; and
configuring the detector to be orthogonal to the TTR signal.

2. The method of claim 1, further comprising:
incorporating a filter within the detector, wherein the filter is matched to the phase change of the pilot tone.

3. The method of claim 2, further comprising:
incorporating a window function within the filter to thereby decrease noise effects.

4. The method of claim 2, further comprising:
the detector, during receipt of a phase change, providing an output defined as:
$${\int }_{- L}^{L} {ⅇ}^{- 1 jω 48 \cdot t} \cdot sgn ( t ) \cdot sin ( ω48 + \frac{π}{2} \cdot φ ( t ) ) ⅆ t := \frac{L \cdot ( 1 + j )}{2}$$

5. The method of claim 2, further comprising configuring the detector with a detection distance defined as:
$$\vert {\int }_{- L}^{L} {ⅇ}^{- 1 j \cdot ω48 t} \cdot sgn ( t ) \cdot sin ( o48 \cdot t + \frac{π}{2} \cdot φ ( t ) ) ⅆ t \vert := \frac{L}{\sqrt{2}}$$

6. The method of claim 2, further comprising:
applying the pilot tone to the filter to generate a metric;
determining a threshold value; and
comparing the metric to the threshold value.

7. The method of claim 6, further comprising:
incorporating discrimination logic to reduce false detection of the phase change.

8. The method of claim 7, further comprising:
the discrimination logic monitoring the number of metrics exceeding the threshold value to determine a false detection of a phase change.

9. The method of claim 7, further comprising:
comparing metrics relating to four previous frames to the threshold value to determine if a metric reflects a false detection of a phase change.

10. A method for aligning a hyperframe in a TCM ISDN environment, the method comprising:
locating a first series of five contiguous FEXT frames;
locating a second series of five contiguous FEXT frames; and
monitoring the number of frames between the first and second series to determine a distance.

11. The method of claim 10, wherein monitoring the number of frames includes incrementing a tracking variable to reflect passage of frames.

12. The method of claim 11, further comprising:
monitoring the tracking variable to determine passage of 97 frames; and
identifying frame 241.

13. The method of claim 10, further comprising initial steps of:
identifying boundaries of NEXT and FEXT frames; and
aligning NEXT and FEXT frames.

14. A method for aligning NEXT and FEXT frames in a TCM ISDN environment, the method comprising:
detecting phase changes in a received tone;
generating metrics that reflect the phase changes;
comparing the metrics to derive detection peaks; and
aligning frame boundaries to the detection peaks.

15. The method of claim 14, further comprising:
verifying the location of detection peaks to the location of frame boundaries.

16. The method of claim 15, further comprising:
incrementing a detection counter to reflect a count of a TTR signal; and
incrementing a total detection counter to reflect a frame count.

17. The method of claim 16, further comprising:
monitoring the total detection counter to determine if a frame threshold count is reached.

18. The method of claim 17, wherein the frame threshold count is 345.

19. The method of claim 14, wherein detecting phase changes includes:
configuring a detector to correlate with the phase changes,
configuring the detector to be orthogonal to the tone in the absence of a phase change, and
configuring the detector to be orthogonal to a TTR signal.

20. The method of claim 19, further comprising:
incorporating a filter within the detector, wherein the filter is matched to the phase changes.

21. The method of claim 20, further comprising:
incorporating a window function within the filter to thereby decrease noise effects.

22. The method of claim 20, further comprising:
applying the tone to the filter to generate metrics,
determining a threshold value, and
comparing the metrics to the threshold value.

23. The method of claim 22, further comprising:
incorporating discrimination logic to reduce false detection of phase changes.

24. The method of claim 23, further comprising:
the discrimination logic monitoring the number of metrics exceeding the threshold value to determine a false detection of a phase change.

25. The method of claim 23, further comprising:
comparing metrics relating to four previous frames to the threshold value to determine if a metric reflects a false detection of a phase change.

26. An ATU-R modem in a TCM ISDN environment for receiving a TTR signal and determining phase changes in a tone signaling half periods of the TTR signal, the ATU-R modem comprising:
a detector for receiving phase changes and generating outputs relating to the phase changes; and
a state machine, in electrical communication with the detector, for determining patterns in the outputs to thereby determine frame alignment and hyperframe alignment.

27. The ATU-R modem of claim 26 wherein the detector is orthogonal to the tone in the absence of a phase change and orthogonal to the TTR signal.

28. The ATU-R modem of claim 26, wherein the detector further comprises:
a filter matched to the phase changes.

29. The ATU-R modem of claim 28 wherein the filter is configured to generate metrics relating to the phase changes and compare the metrics to a threshold value.

30. The ATU-R modem of claim 26 wherein the state machine is configured to identify boundaries of frames, locate a first series of five contiguous FEXT frames, locate a second series of five contiguous FEXT frames, and determine the distance between the first and second series to find hyperframe alignment.

31. A method for achieving hyperframe alignment for a G.lite/G.dmt Annex C CPE Modem, the method comprising:
locating a first set of second pilot tone phase changes that are separated by five DSL frames;
locating a second set of second pilot tone phase changes that are separated by five DSL frames; and
monitoring the number of frames between the first set and the second set to determine which frame within the hyperframe is currently being processed.
